(19) United States
(12) Patent Application Publication
(10) Pub. No.: US 2026/0255581 A1
(43) Pub. Date: Aug. 27, 2026

(54) MEMORY STRUCTURE

(71) Applicant: Powerchip Semiconductor Manufacturing Corporation, Hsinchu (TW)

(72) Inventor: Jia-Horng Tsai, New Taipei City (TW)

(73) Assignee: Powerchip Semiconductor Manufacturing Corporation, Hsinchu (TW)

(21) Appl. No.: 19/082,221

(22) Filed: Mar. 18, 2025

(30) Foreign Application Priority Data
Feb. 24, 2025 (TW) 114106674

(51) Int. Cl. H10B 12/00

(52) U.S. Cl. CPC H10B 12/34; H10B 12/0335; H10B 12/036; H10B 12/053; H10B 12/315; H10B 12/33; H10B 12/485

(57) ABSTRACT

A memory structure including a substrate, first and second word line structures, a bit line structure, a first contact structure, a first capacitor structure, a second contact structure, and a second capacitor structure is provided. The substrate includes a first side and a second side opposite to each other. The first word line structure and the second word line structure are located in the substrate. The bit line structure is located on the first side and between the first word line structure and the second word line structure. The first contact structure is located on the first side and on one side of the bit line structure. The first capacitor structure is located on the first side and on the first contact structure. The second contact structure is located on the second side. The second capacitor structure is located on the second side and on the second contact structure.

### CROSS-REFERENCE TO RELATED APPLICATION

This application claims the priority benefit of Taiwan application serial no. 114106674 filed on Feb. 24, 2025. The entirety of the above-mentioned patent application is hereby incorporated by reference herein and made a part of this specification.

### BACKGROUND

### Technical Field

The invention relates to a semiconductor structure, and particularly relates to a memory structure.

### Description of Related Art

The memory device is widely used in the electronic product. However, as the size of the memory device continues to shrink, how to effectively reduce the area of the memory cell is the goal of continuous efforts.

### SUMMARY

The invention provides a memory structure, which can effectively reduce the area of the memory cell.

The invention provides a memory structure, which includes a substrate, a first word line structure, a second word line structure, a bit line structure, a first contact structure, a first capacitor structure, a second contact structure, and a second capacitor structure. The substrate includes a first side and a second side opposite to each other. The first word line structure and the second word line structure are located in the substrate. The bit line structure is located on the first side and between the first word line structure and the second word line structure. The first contact structure is located on the first side and on one side of the bit line structure. The first capacitor structure is located on the first side and on the first contact structure. The second contact structure is located on the second side. The second capacitor structure is located on the second side and on the second contact structure.

According to an embodiment of the invention, in the memory structure, the first word line structure and the second word line structure may be electrically insulated from the substrate.

According to an embodiment of the invention, in the memory structure, the first word line structure may be located between the bit line structure and the first contact structure.

According to an embodiment of the invention, in the memory structure, the first word line structure and the second word line structure may extend from the first side toward the second side.

According to an embodiment of the invention, in the memory structure, the depth of the second word line structure may be greater than the depth of the first word line structure.

According to an embodiment of the invention, in the memory structure, the bit line structure may be connected to the substrate.

According to an embodiment of the invention, in the memory structure, the bit line structure may include a bit line and a contact. The bit line is located on the substrate. The contact is located between the bit line and the substrate.

According to an embodiment of the invention, in the memory structure, the first contact structure may be connected to the substrate.

According to an embodiment of the invention, in the memory structure, the first contact structure may include a first contact, a second contact, and a barrier layer. The first contact is connected to the substrate. The second contact is located on the first contact. The barrier layer is located between the first contact and the second contact.

According to an embodiment of the invention, in the memory structure, the first capacitor structure may be electrically connected to the first contact structure.

According to an embodiment of the invention, in the memory structure, the first capacitor structure may include a first electrode layer, a second electrode layer, and a dielectric layer. The first electrode layer is electrically connected to the first contact structure. The second electrode layer is located on the first electrode layer. The dielectric layer is located between the first electrode layer and the second electrode layer.

According to an embodiment of the invention, in the memory structure, the second contact structure may be connected to the substrate.

According to an embodiment of the invention, in the memory structure, the second contact structure may extend into the substrate.

According to an embodiment of the invention, in the memory structure, the top view pattern of the second contact structure may overlap the top view pattern of the second word line structure,

According to an embodiment of the invention, in the memory structure, the second contact structure may include a first contact, a second contact, and a barrier layer. The first contact is connected to the substrate. The second contact is located on the first contact. The barrier layer is located between the first contact and the second contact.

According to an embodiment of the invention, in the memory structure, the second capacitor structure may be electrically connected to the second contact structure.

According to an embodiment of the invention, in the memory structure, the second capacitor structure may include a first electrode layer, a second electrode layer, and a dielectric layer. The first electrode layer is electrically connected to the second contact structure. The second electrode layer is located on the first electrode layer. The dielectric layer is located between the first electrode layer and the second electrode layer.

According to an embodiment of the invention, the memory structure may further include a first dielectric structure and a second dielectric structure. The first dielectric structure and the second dielectric structure are located in the substrate. The first word line structure may be located in the first dielectric structure. The second word line structure may be located in the second dielectric structure.

According to an embodiment of the invention, in the memory structure, the first dielectric structure and the second dielectric structure may extend from the first side toward the second side.

According to an embodiment of the invention, in the memory structure, the depth of the second dielectric structure may be greater than the depth of the first dielectric structure.

Based on the above description, in the memory structure according to the invention, since the first contact structure and the first capacitor structure are located on the first side, and the second contact structure and the second capacitor structure are located on the second side, the area of the memory cell can be effectively reduced. In addition, since the first capacitor structure and the second capacitor structure are respectively located on the first side and the second side, the area of the first capacitor structure and the area of the second capacitor structure can be maximized, thereby increasing the capacitance of the first capacitor structure and the capacitance of the second capacitor structure.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a memory structure according to some embodiments of the invention.

FIG. 2A to FIG. 2F are cross-sectional views of a manufacturing process of a memory structure taken along section line I-I′ in FIG. 1.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

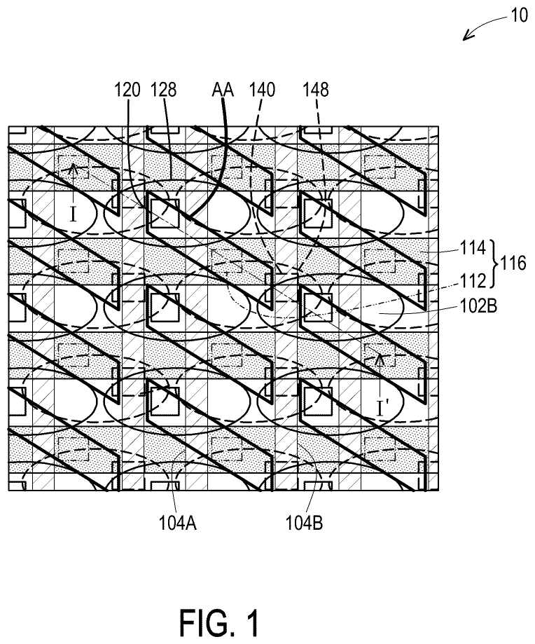

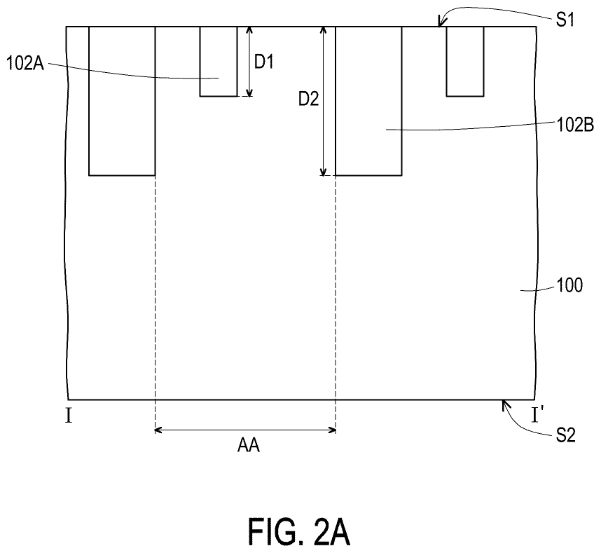

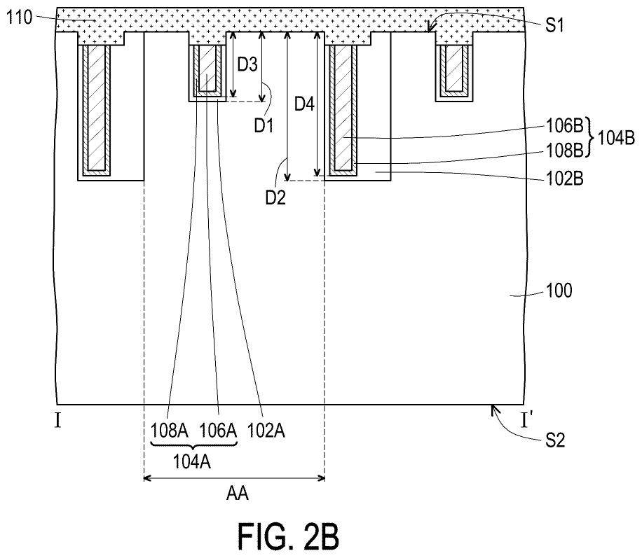

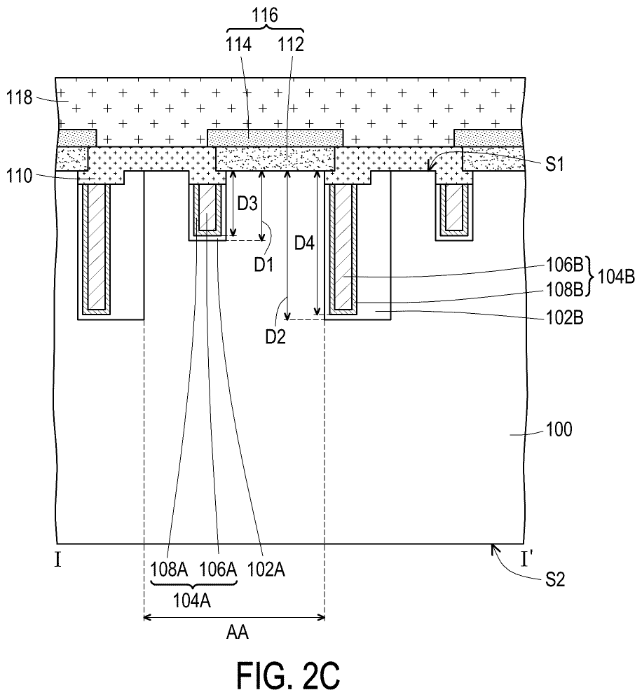

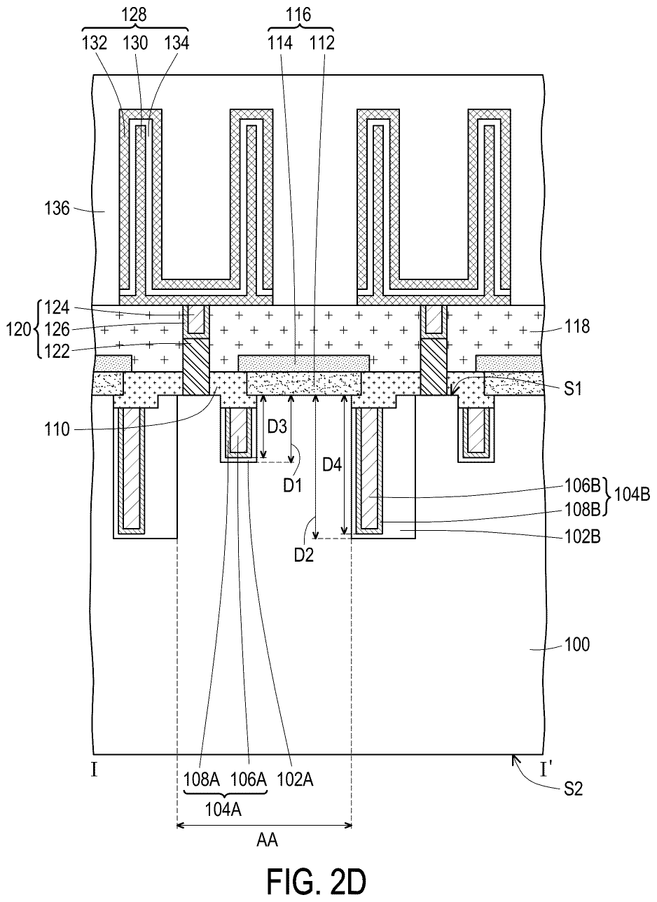

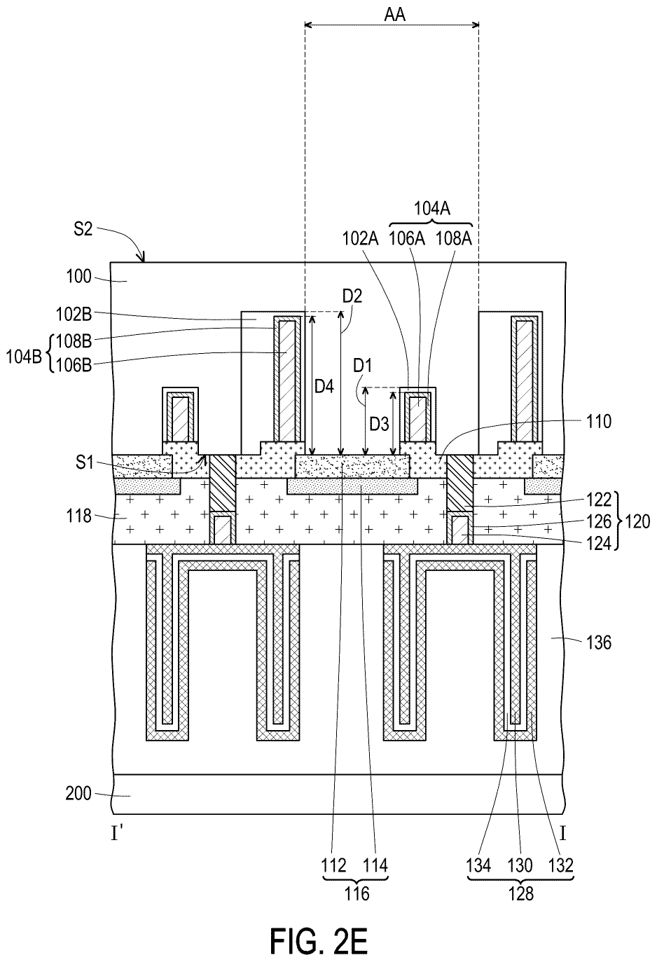

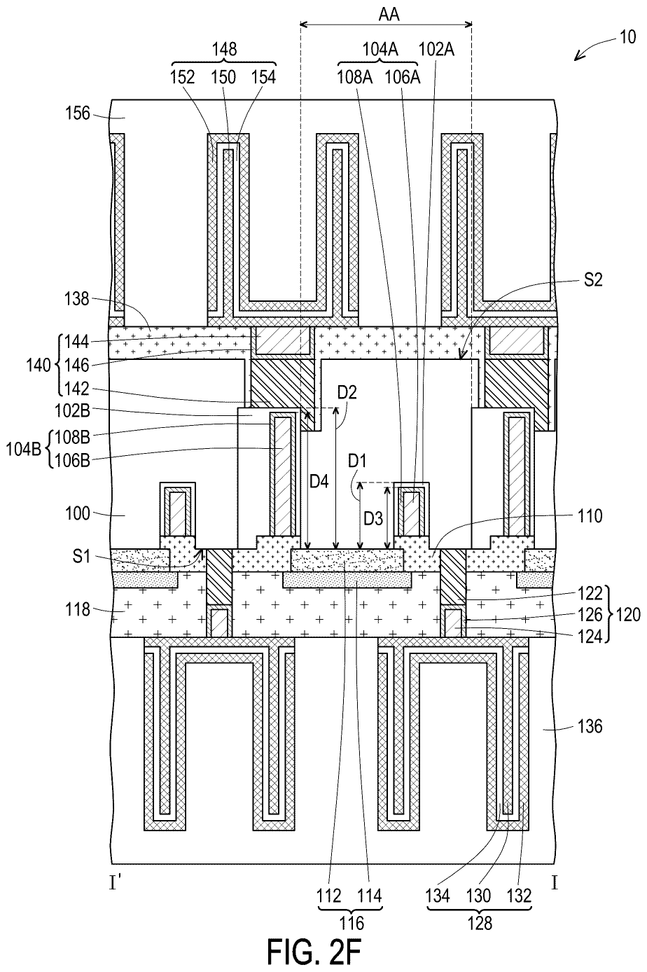

FIG. 1 is a top view of a memory structure according to some embodiments of the invention. FIG. 2A to FIG. 2F are cross-sectional views of a manufacturing process of a memory structure taken along section line I-I′ in FIG. 1. In FIG. 1, some components in FIG. 2A to FIG. 2F may be omitted to clearly illustrate the configuration relationship between the components in FIG. 1.

Referring to FIG. 1 and FIG. 2A, a substrate 100 is provided. The substrate 100 includes a first side S1 and a second side S2 opposite to each other. In some embodiments, the first side S1 may be the front side of the substrate 100, and the second side S2 may be the back side of the substrate 100. In some embodiments, the substrate 100 may be a semiconductor substrate such as a silicon substrate. In some embodiments, there may be required doped regions (not shown) in the substrate 100, and the description thereof is omitted here.

A dielectric structure 102A and a dielectric structure 102B may be formed in the substrate 100. The dielectric structure 102B may define an active region AA in the substrate 100. In some embodiments, the dielectric structure 102A and the dielectric structure 102B may extend from the first side S1 toward the second side S2. In some embodiments, the depth D2 of the dielectric structure 102B may be greater than the depth D1 of the dielectric structure 102A. In some embodiments, the dielectric structure 102A and the dielectric structure 102B may be shallow trench isolation (STI) structures. In some embodiments, the material of the dielectric structure 102A and the material of the dielectric structure 102B are, for example, silicon oxide.

Referring to FIG. 1 and FIG. 2B, a word line structure 104A may be formed in the dielectric structure 102A, and a word line structure 104B may be formed in the dielectric structure 102B. Therefore, the word line structure 104A and the word line structure 104B may be formed in the substrate 100. The word line structure 104A and the word line structure 104B may be electrically insulated from the substrate 100. For example, the word line structure 104A may be electrically insulated from the substrate 100 by the dielectric structure 102A, and the word line structure 104B may be electrically insulated from the substrate 100 by the dielectric structure 102B. In some embodiments, the word line structure 104A and the word line structure 104B may extend from the first side S1 toward the second side S2. In some embodiments, the depth D4 of the word line structure 104B may be greater than the depth D3 of the word line structure 104A. In some embodiments, the top view pattern of the word line structure 104B does not overlap the top view pattern of the active region AA.

In some embodiments, the word line structure 104A may include a word line 106A. The word line 106A is located in the dielectric structure 102A. In some embodiments, the word line structure 104A may further include a barrier layer 108A. The barrier layer 108A is located between the word line 106A and the dielectric structure 102A. In some embodiments, the material of the word line 106A is, for example, tungsten. In some embodiments, the material of the barrier layer 108A is, for example, titanium, titanium nitride, or a combination thereof.

In some embodiments, the word line structure 104B may include a word line 106B. The word line 106B is located in the dielectric structure 102B. In some embodiments, the word line structure 104B may further include a barrier layer 108B. The barrier layer 108B is located between the word line 106B and the dielectric structure 102B. In some embodiments, the material of the word line 106B is, for example, tungsten. In some embodiments, the material of the barrier layer 108B is, for example, titanium, titanium nitride, or a combination thereof.

A cap layer 110 may be formed on the substrate 100, the dielectric structure 102A, the dielectric structure 102B, the word line structure 104A, and the word line structure 104B. In some embodiments, the material of the cap layer 110 is, for example, silicon nitride.

Referring to FIG. 1 and FIG. 2C, a contact 112 may be formed in the cap layer 110. The contact 112 may be connected to the substrate 100. In some embodiments, the material of the contact 112 is, for example, doped polysilicon. A bit line 114 may be formed on the contact 112. In some embodiments, the material of the bit line 114 is, for example, tungsten. By the above method, the bit line structure 116 may be formed on the first side S1. The bit line structure 116 is located on the first side S1 and between the word line structure 104A and the word line structure 104B. The bit line structure 116 may include a bit line 114 and a contact 112. The bit line structure 116 may be connected to the substrate 100. The bit line 114 is located on the substrate 100. The contact 112 is located between the bit line 114 and the substrate 100. The contact 112 may be connected to the substrate 100.

A dielectric layer 118 may be formed on the cap layer 110 and the bit line structure 116. In some embodiments, the material of the dielectric layer 118 is, for example, silicon nitride.

Referring to FIG. 1 and FIG. 2D, a contact structure 120 may be formed in the dielectric layer 118 and the cap layer 110. Therefore, the contact structure 120 may be formed on the first side S1. The contact structure 120 is located on one side of the bit line structure 116. The contact structure 120 may be connected to the substrate 100. In addition, the word line structure 104A may be located between the bit line structure 116 and the contact structure 120. In some embodiments, the contact structure 120 may include a contact 122, a contact 124, and a barrier layer 126. The contact 122 may be connected to the substrate 100. In some embodiments, the material of the contact 122 is, for example, doped polysilicon. The contact 124 is located on the contact 122. In some embodiments, the material of the contact 124 is, for example, tungsten. The barrier layer 126 is located between the contact 122 and the contact 124 and may be located between the contact 124 and the dielectric layer 118. In some embodiments, the material of the barrier layer 126 is, for example, titanium, titanium nitride, or a combination thereof.

A capacitor structure 128 may be formed on the first side S1. The capacitor structure 128 is located on the contact structure 120. The capacitor structure 128 may be electrically connected to the contact structure 120. In some embodiments, the capacitor structure 128 may include an electrode layer 130, an electrode layer 132, and a dielectric layer 134. The electrode layer 130 is electrically connected to the contact structure 120. In some embodiments, the material of the electrode layer 130 is, for example, titanium, titanium nitride, or a combination thereof. The electrode layer 132 is located on the electrode layer 130. In some embodiments, the material of the electrode layer 132 is, for example, titanium, titanium nitride, or a combination thereof. The dielectric layer 134 is located between the electrode layer 130 and the electrode layer 132. In some embodiments, the material of the dielectric layer 134 is, for example, a high dielectric constant material.

A dielectric layer 136 may be formed on the dielectric layer 118 and the capacitor structure 128. In some embodiments, the material of the dielectric layer 136 is, for example, silicon oxide.

Referring to FIG. 2E, the dielectric layer 136 may be bonded onto a carrier substrate 200. A thinning process may be performed on the second side S2 of the substrate 100 to reduce the thickness of the substrate 100.

Referring to FIG. 1 and FIG. 2F, a dielectric layer 138 may be formed on the second side S2 and in the substrate 100. The dielectric layer 138 may be a single-layer structure or a multilayer structure. A contact structure 140 may be formed in the dielectric layer 138. Therefore, the contact structure 140 may be formed on the second side S2. The contact structure 140 may be connected to the substrate 100. In some embodiments, the contact structure 140 may extend into the substrate 100. In some embodiments, the top view pattern of the contact structure 140 may overlap the top view pattern of the word line structure 104B. In some embodiments, the contact structure 140 may include a contact 142, a contact 144, and a barrier layer 146. The contact 142 is connected to the substrate 100. The contact 142 may be located in the substrate 100. In some embodiments, the material of the contact 142 is, for example, doped polysilicon. The contact 144 is located on the contact 142. In some embodiments, the material of the contact 144 is, for example, tungsten. The barrier layer 146 is located between the contact 142 and the contact 144 and may be located between the contact 144 and the dielectric layer 138. In some embodiments, the material of the barrier layer 146 is, for example, titanium, titanium nitride, or a combination thereof.

A capacitor structure 148 may be formed on the second side S2. The capacitor structure 148 is located on the contact structure 140. The capacitor structure 148 may be electrically connected to the contact structure 140. In some embodiments, the capacitor structure 148 may include an electrode layer 150, an electrode layer 152, and a dielectric layer 154. The electrode layer 150 is electrically connected to the contact structure 140. In some embodiments, the material of the electrode layer 150 is, for example, titanium, titanium nitride, or a combination thereof. The electrode layer 152 is located on the electrode layer 150. In some embodiments, the material of the electrode layer 152 is, for example, titanium, titanium nitride, or a combination thereof. The dielectric layer 154 is located between the electrode layer 150 and the electrode layer 152. In some embodiments, the material of dielectric layer 154 is, for example, a high dielectric constant material.

A dielectric layer 156 may be formed on the dielectric layer 138 and the capacitor structure 148. In some embodiments, the material of the dielectric layer 156 is, for example, silicon oxide. Furthermore, the carrier substrate 200 may be removed.

Hereinafter, the memory structure 10 of the above embodiments will be described with reference to FIG. 1 and FIG. 2F. In addition, although the forming method of the memory structure 10 is described by taking the above-mentioned method as an example, the invention is not limited thereto.

Referring to FIG. 1 and FIG. 2F, the memory structure 10 includes a substrate 100, a word line structure 104A, a word line structure 104B, a bit line structure 116, a contact structure 120, a capacitor structure 128, a contact structure 140, and a capacitor structure 148. The memory structure 10 is applicable to a wafer-on-wafer (WoW) process and a through substrate via (TSV) process. The substrate 100 includes a first side S1 and a second side S2 opposite to each other. The word line structure 104A and the word line structure 104B are located in the substrate 100. The bit line structure 116 is located on the first side S1 and between the word line structure 104A and the word line structure 104B. The contact structure 120 is located on the first side S1 and on one side of the bit line structure 116. The capacitor structure 128 is located on the first side S1 and on the contact structure 120. The contact structure 140 is located on the second side S2. The capacitor structure 148 is located on the second side S2 and on the contact structure 140. In addition, the memory structure 10 may further include a dielectric structure 102A and a dielectric structure 102B. The dielectric structure 102A and the dielectric structure 102B are located in the substrate 100. The word line structure 104A may be located in the dielectric structure 102A. The word line structure 104B may be located in the dielectric structure 102B.
Furthermore, the remaining components in the memory structure 10 may refer to the description of the above embodiments. Moreover, the details (e.g., material and forming method) of the components in the memory structure 10 have been described in detail in the above embodiments, and the description thereof is not repeated here.

Based on the above embodiments, in the memory structure 10 according to the invention, since the contact structure 120 and the capacitor structure 128 are located on the first side S1, and the contact structure 140 and the capacitor structure 148 are located on the second side S2, the area of the memory cell can be effectively reduced. In addition, since the capacitor structure 128 and the capacitor structure 148 are respectively located on the first side S1 and the second side S2, the area of the capacitor structure 128 and the area of the second capacitor structure 148 can be maximized, thereby increasing the capacitance of the capacitor structure 128 and the capacitance of the capacitor structure 148.

In summary, a memory structure of the aforementioned embodiments includes a substrate, a first word line structure, a second word line structure, a bit line structure, a first contact structure, a first capacitor structure, a second contact structure, and a second capacitor structure. The substrate includes a first side and a second side opposite to each other. The first word line structure and the second word line structure are located in the substrate. The bit line structure is located on the first side and between the first word line structure and the second word line structure. The first contact structure is located on the first side and on one side of the bit line structure. The first capacitor structure is located on the first side and on the first contact structure. The second contact structure is located on the second side. The second capacitor structure is located on the second side and on the second contact structure. Therefore, the area of the memory cell can be effectively reduced. In addition, the area of the first capacitor structure and the area of the second capacitor structure can be maximized, thereby increasing the capacitance of the first capacitor structure and the capacitance of the second capacitor structure.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A memory structure comprising:
a substrate comprising a first side and a second side opposite to each other;
a first word line structure and a second word line structure located in the substrate;
a bit line structure located on the first side and between the first word line structure and the second word line structure;
a first contact structure located on the first side and on one side of the bit line structure;
a first capacitor structure located on the first side and on the first contact structure;
a second contact structure located on the second side; and
a second capacitor structure located on the second side and on the second contact structure.

2. The memory structure according to claim 1, wherein the first word line structure and the second word line structure are electrically insulated from the substrate.

3. The memory structure according to claim 1, wherein the first word line structure is located between the bit line structure and the first contact structure.

4. The memory structure according to claim 1, wherein the first word line structure and the second word line structure extend from the first side toward the second side.

5. The memory structure according to claim 4, wherein a depth of the second word line structure is greater than a depth of the first word line structure.

6. The memory structure according to claim 1, wherein the bit line structure is connected to the substrate.

7. The memory structure according to claim 1, wherein the bit line structure comprises:
a bit line located on the substrate; and
a contact located between the bit line and the substrate.

8. The memory structure according to claim 1, wherein the first contact structure is connected to the substrate.

9. The memory structure according to claim 1, wherein the first contact structure comprises:
a first contact connected to the substrate;
a second contact located on the first contact; and
a barrier layer located between the first contact and the second contact.

10. The memory structure according to claim 1, wherein the first capacitor structure is electrically connected to the first contact structure.

11. The memory structure according to claim 1, wherein the first capacitor structure comprises:
a first electrode layer electrically connected to the first contact structure;
a second electrode layer located on the first electrode layer; and
a dielectric layer located between the first electrode layer and the second electrode layer.

12. The memory structure according to claim 1, wherein the second contact structure is connected to the substrate.

13. The memory structure according to claim 1, wherein the second contact structure extends into the substrate.

14. The memory structure according to claim 1, wherein a top view pattern of the second contact structure overlaps a top view pattern of the second word line structure.

15. The memory structure according to claim 1, wherein the second contact structure comprises:
a first contact connected to the substrate;
a second contact located on the first contact; and
a barrier layer located between the first contact and the second contact.

16. The memory structure according to claim 1, wherein the second capacitor structure is electrically connected to the second contact structure.

17. The memory structure according to claim 1, wherein the second capacitor structure comprises:
a first electrode layer electrically connected to the second contact structure;
a second electrode layer located on the first electrode layer; and
a dielectric layer located between the first electrode layer and the second electrode layer.

18. The memory structure according to claim 1, further comprising:
a first dielectric structure and the second dielectric structure located in the substrate, wherein the first word line structure is located in the first dielectric structure, and the second word line structure is located in the second dielectric structure.

19. The memory structure according to claim 18, wherein the first dielectric structure and the second dielectric structure extend from the first side toward the second side.

20. The memory structure according to claim 19, wherein a depth of the second dielectric structure is greater than a depth of the first dielectric structure.
